(19) United States
(12) Patent Application Publication
(10) Pub. No.: US 2024/0244848 A1
(43) Pub. Date: Jul. 18, 2024

(54) SEMICONDUCTOR DEVICE INCLUDING FERROELECTRIC LAYER

(71) Applicant: Samsung Electronics Co., Ltd., Suwon-si (KR)

(72) Inventors: Hyunjae LEE, Suwon-si (KR); Jinseong HEO, Suwon-si (KR); Seunggeol NAM, Suwon-si (KR); Yunseong LEE, Suwon-si (KR); Dukhyun CHOE, Suwon-si (KR)

(73) Assignee: Samsung Electronics Co., Ltd., Suwon-si (KR)

(21) Appl. No.: 18/412,793

(22) Filed: Jan. 15, 2024

(30) Foreign Application Priority Data
Jan. 13, 2023 (KR) 10-2023-0005635

(51) Int. Cl. H10B 51/30; H10B 51/20

(52) U.S. Cl. CPC H10B 51/30; H10B 51/20

(57) ABSTRACT

Provided is a semiconductor device including a ferroelectric layer. The semiconductor device includes a channel layer including an n-type oxide semiconductor layer and a p-type oxide semiconductor layer, a ferroelectric layer disposed on the channel layer, a gate electrode disposed on the ferroelectric layer, and a reduced layer disposed on the channel layer and including an element having greater reducing power than a metal included in the channel layer.

### CROSS-REFERENCE TO RELATED APPLICATION

This application is based on and claims priority under 35 U.S.C. § 119 to Korean Patent Application No. 10-2023-0005635, filed on Jan. 13, 2023, in the Korean Intellectual Property Office, the disclosure of which is incorporated by reference herein in its entirety.

### BACKGROUND

### 1. Field

The disclosure relates to semiconductor devices including a ferroelectric layer and/or electronic apparatuses including the semiconductor device.

### 2. Description of the Related Art

A ferroelectric is a material with ferroelectricity that maintain spontaneous polarization by aligning internal electric dipole moments even though an electric field is not applied from the outside. Research on applying these ferroelectric characteristics to logic devices or memory devices continues.

### SUMMARY

Provided are semiconductor devices including a ferroelectric layer and electronic apparatuses including the semiconductor device

Additional aspects will be set forth in part in the description which follows and, in part, will be apparent from the description, or may be learned by practice of the presented embodiments of the disclosure.

According to an example embodiment of the disclosure, a semiconductor device includes a channel layer including an n-type oxide semiconductor layer and a p-type oxide semiconductor layer, a ferroelectric layer on the channel layer, a gate electrode on the ferroelectric layer, and a reduced layer on the channel layer and including an element having greater reducing power than a metal included in the channel layer.

The element included in reduced layer may include metal having greater reducing power than a metal included in the channel layer.

The n-type oxide semiconductor layer and the p-type oxide semiconductor layer may include different oxygen contents.

The reduced layer may be in contact with one of the n-type oxide semiconductor layer and the p-type oxide semiconductor layer that has a relatively low oxygen content.

The reduced layer may be spaced apart from one of the n-type oxide semiconductor layer and the p-type oxide semiconductor layer, and in contact with the other one of the n-type oxide semiconductor layer and the p-type oxide semiconductor layer.

A thickness of one of the n-type oxide semiconductor layer and the p-type oxide semiconductor layer that is in contact with the reduced layer may be less than a thickness of the other one of the n-type oxide semiconductor layer and the p-type oxide semiconductor layer that is spaced apart from the reduced layer.

A thickness of the reduced layer may be less than or equal to a thickness of one of the n-type oxide semiconductor layer and the p-type oxide semiconductor layer that is \ in contact with the reduced layer.

The n-type oxide semiconductor layer and the p-type oxide semiconductor layer may include same metal.

The reduced layer may be between the ferroelectric layer and the channel layer.

The n-type oxide semiconductor layer and the p-type oxide semiconductor layer may be parallel to each other in a thickness direction of the channel layer.

The thickness of the reduced layer may be 1 nm or less.

At least one of the n-type oxide semiconductor layer and the p-type oxide semiconductor layer may include at least one of indium oxide, zinc oxide, tin oxide, nickel oxide, and gallium oxide

The reduced layer may include at least one of aluminum oxide, hafnium oxide, and silicon oxide.

The semiconductor device may further include a source electrode on the channel layer and spaced apart from the gate electrode, and a drain electrode on the channel layer and spaced apart from the gate electrode and the source electrode.

The semiconductor device may further include a pillar extending in a first direction, wherein the channel layer surrounds the pillar, the ferroelectric layer surrounds the channel layer, the gate electrode surrounds the ferroelectric layer, and the reduced layer is between the pillar and the channel layer.

The n-type oxide semiconductor layer and the p-type oxide semiconductor layer may be parallel in a direction perpendicular to the first direction.

The gate electrode may include a plurality of gate electrodes being apart from each other in the first direction.

The n-type oxide semiconductor layer and the p-type oxide semiconductor layer may be parallel with each other in a direction perpendicular to a thickness direction of the channel layer, the ferroelectric layer may include a first ferroelectric layer on the n-type oxide semiconductor layer and a second ferroelectric layer on the p-type oxide semiconductor layer and spaced apart from the first ferroelectric layer, the gate electrode may include a first gate electrode on the first ferroelectric layer, and a second gate electrode on the second ferroelectric layer and spaced apart from the first gate electrode, and the reduced layer may be in contact with one of the n-type oxide semiconductor layer and the p-type oxide semiconductor layer and is not in contact with the other one of the n-type oxide semiconductor layer and the p-type oxide semiconductor layer.

A thickness of the n-type oxide semiconductor layer may be substantially same as a thickness of the p-type oxide semiconductor layer.

The semiconductor device may further include a common drain electrode in contact with both the n-type oxide semiconductor layer and the p-type oxide semiconductor layer, a first source electrode in contact with the n-type oxide semiconductor layer, and a second source electrode in contact with the p-type oxide semiconductor layer.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a schematic cross-sectional view of a semiconductor device according to an example embodiment;

FIG. 2 is a schematic cross-sectional view of a semiconductor device according to an example embodiment;

FIGS. 3A and 3B are diagrams for explaining an operation of a conventional ferroelectric field effect transistor;

FIG. 4 illustrates a polarization state within a ferroelectric layer when a (−) voltage is applied to a gate electrode in a semiconductor device according to an example embodiment;

FIG. 5 shows an equivalent circuit diagram of a memory device including the semiconductor device according to the example embodiment shown in FIG. 2;

FIG. 6 is a perspective view of a semiconductor device according to an example embodiment;

FIG. 7 is an enlarged cross-sectional view of portion ‘A’ of FIG. 6;

FIG. 8 is a cross-sectional view of a semiconductor device according to an example embodiment;

FIG. 9 is a cross-sectional view of a semiconductor device that does not include a reduced layer according to an example embodiment;

FIG. 10 is a schematic block diagram of a display driver integrated circuit (DDI) and a display device including the DDI, according to an example embodiment;

FIG. 11 is a block diagram of an electronic apparatus according to an example embodiment;

FIG. 12 is a block diagram of an electronic apparatus according to an example embodiment;

FIGS. 13 and 14 are conceptual diagrams schematically showing a device architecture that may be applied to an electronic apparatus according to an example embodiment; and

FIG. 15 is a diagram showing a circuit applied to an artificial intelligence device according to an example embodiment.

### DETAILED DESCRIPTION

Reference will now be made in detail to some example embodiments, which are illustrated in the accompanying drawings, wherein like reference numerals refer to like elements throughout. In this regard, the present example embodiments may have different forms and should not be construed as being limited to the descriptions set forth herein. Accordingly, the present example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments will be described more fully with reference to the accompanying drawings. Hereinafter, like reference numerals in the drawings refer to like elements throughout, and sizes of elements in the drawings may be exaggerated for clarity and convenience of explanation. The present example embodiments of the disclosure are capable of various modifications and may be embodied in many different forms.

In a layer structure described below, when a position of an element is described using an expression “above” or “on”, the position of the element may include not only the element being “immediately in a contact manner” but also being in a non-contact manner”. The singular forms include the plural forms unless the context clearly indicates otherwise. When a portion “includes” an element, another element may be further included, rather than excluding the existence of the other element, unless otherwise described.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the terms “units” or “. . . modules” denote units or modules that process at least one function or operation, and may be realized by hardware, software, or a combination of hardware and software.

Although first, second, etc. are used to describe various components, these components are of course not limited by these terms. These terms are only used to distinguish one component from another component.

Connections or connection members of lines between components shown in the drawings illustrate functional connections and/or physical or circuit connections, and the connections or connection members may be represented by replaceable or additional various functional connections, physical connections, or circuit connections in an actual apparatus.

While the term “same,” “equal” or “identical” is used in description of the present example embodiments, it should be understood that some imprecisions may exist.

Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

All examples or example terms are simply used to explain in detail the technical scope of the disclosure, and thus, the scope of the disclosure is not limited by the examples or the example terms as long as it is not defined by the claims.

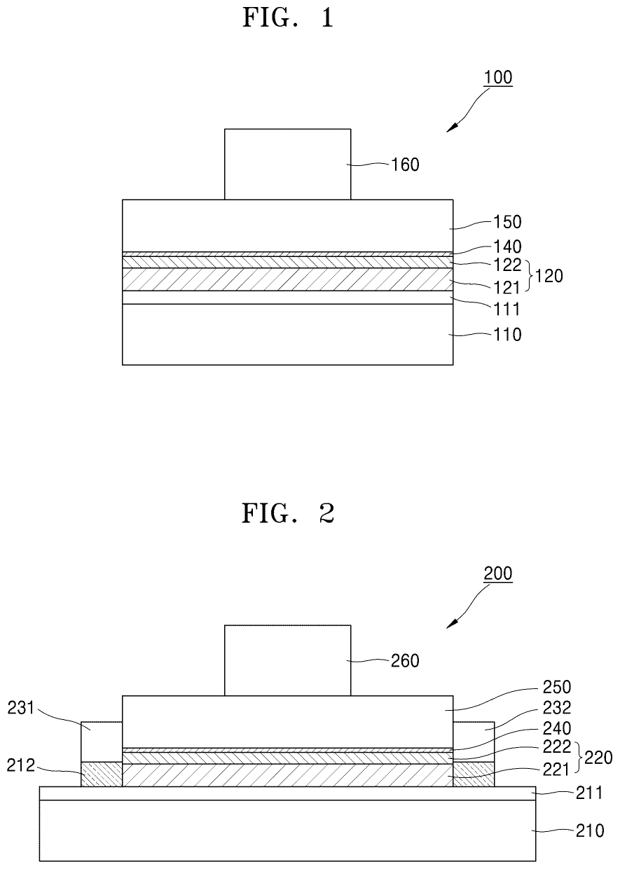

FIG. 1 is a cross-sectional view of a semiconductor device 100 according to an example embodiment.

Referring to FIG. 1, the semiconductor device 100 includes a substrate 110, a channel layer 120 on the substrate 110, a reduced layer 140 on the channel layer 120, a ferroelectric layer 150 on the reduced layer 140, and a gate electrode 160 on the ferroelectric layer 150. The semiconductor device 100 may further include an insulating layer 111 disposed between the substrate 110 and the channel layer 120.

The substrate 110 may include a Group IV semiconductor material doped with a dopant of a desired (or alternatively, predetermined) polarity. Here, the Group IV semiconductor material may include, for example, Si, Ge, or SiGe. However, example embodiments are not limited thereto.

The channel layer 120 is provided on the substrate 110. The channel layer 120 may include a first oxide semiconductor layer 121 and a second oxide semiconductor layer 122 that have different polarities from each other. One of the first oxide semiconductor layer 121 and the second oxide semiconductor layer 122 may include majority carriers of the channel layer 120, and the other layer may include minority carriers. Among the first oxide semiconductor layer 121 and the second oxide semiconductor layer 122, a layer adjacent to the ferroelectric layer 140 may include majority carriers, and a layer that is not adjacent to the ferroelectric layer 140 may include minority carriers. For example, the first oxide semiconductor layer 121 may include minority carriers, and the second oxide positive conductor layer 122 may include majority carriers. The thickness of the first oxide semiconductor layer 121 may be greater than or equal to the thickness of the second oxide semiconductor layer 122.

For example, the second oxide semiconductor layer 122 may include an n-type oxide semiconductor including electrons as majority carriers. For example, the n-type oxide semiconductor may include at least one oxide selected from In, Ga, Zn, and Sn. As a specific example, the n-type oxide semiconductor may include Indium Gallium Zinc Oxide (IGZO). However, this is just an example.

In some example embodiments, the second oxide semiconductor layer 122 may include a p-type oxide semiconductor including holes as majority carriers. The p-type oxide semiconductor may include, for example, an oxide including at least one of Sn and Ni. As a specific example, the p-type oxide semiconductor may include SnO. However, this is just an example.

From another viewpoint, the first oxide semiconductor layer 121 and the second oxide semiconductor layer 122 may have different oxygen contents from each other while including an oxide semiconductor. The oxygen content of the first oxide semiconductor layer 121 may be greater than that of the second oxide semiconductor layer 122. For example, when the first oxide semiconductor layer 121 includes SnO₂, the second oxide semiconductor layer 122 may include SnO. When the first oxide semiconductor layer 121 includes NiO, the second oxide semiconductor layer 122 may include NiO_{1-x(0<x<1)}. However, example embodiments are not limited thereto. The first oxide semiconductor layer 121 and the second oxide semiconductor layer 122 may have different oxygen contents while including different types of oxide semiconductors. Due to different oxygen contents, the first oxide semiconductor layer 121 and the second oxide semiconductor layer 122 may have semiconductor characteristics of different polarities.

The reduced layer 140 including an element with greater reducing power than the metal included in the channel layer 120 may be disposed on the channel layer 120. The reduced layer 140 may be a layer formed by reducing at least a portion of the oxide semiconductor layer that becomes the channel layer 120. The reduced layer 140 may become a metal oxide by obtaining oxygen from the oxide semiconductor layer based on a metal precursor. For example, the reduced layer 140 may include aluminum oxide, hafnium oxide, or silicon oxide. However, example embodiments are not necessarily limited thereto. For example, the reduced layer 140 may be formed through an atomic layer deposition (ALD) process using a metal precursor on an oxide semiconductor layer. The metal precursor may be a material with greater reducing power than the metal included in the channel layer 120. The metal precursor may include at least one of Al, Hf, and Si.

One region (e.g., a portion) of the oxide semiconductor layer may be reduced by a metal precursor having high reducing power. A non-reduced region of the oxide semiconductor layer may become the first oxide semiconductor layer 121, and the reduced region of the oxide semiconductor layer may become the second oxide semiconductor layer 122. Also, a layer formed by oxidizing the metal precursor may become the reduced layer 140. That is, the reduced layer 140 may be in contact with the second oxide semiconductor layer 122, which is a reduced region of the oxide semiconductor layer, and may be spaced apart from the first oxide semiconductor layer 121, which is a non-reduced region. The thickness of the second oxide semiconductor layer 122, which is a reduced region, may be less than or equal to the thickness of the first oxide semiconductor layer 121, which is a non-reduced region. For example, when an ALD process is performed on one surface of an oxide semiconductor layer including SnO₂, which has n-type semiconductor properties, with a metal precursor (e.g., Al) having greater reducing power than Sn, one region of the oxide semiconductor layer is reduced to SnO. SnO has p-type semiconductor characteristics.

The first oxide semiconductor layer 121 and the second oxide semiconductor layer 122 may include the same element, and the same element may include, for example, tin (Sn) oxide, but is not necessarily limited thereto. The first oxide semiconductor layer 121 and the second oxide semiconductor layer 122 may have different oxygen contents while including the same metal oxide.

The first oxide semiconductor layer 121 and the second oxide semiconductor layer 122 may include different elements from each other, for example, the first oxide semiconductor layer 121 may exist in a form in which In, Ga, Zn, and oxygen are combined, and the second oxide semiconductor layer 122 may include tin (Sn) oxide, but is not necessarily limited thereto and may include various elements.

The reduced layer 140 may contact a layer having a low oxygen content among the first oxide semiconductor layer 121 and the second oxide semiconductor layer 122. The thickness of the reduced layer 140 may be less than or equal to the thickness of an adjacent oxide semiconductor layer. For example, the thickness of the reduced layer 140 may be less than or equal to the thickness of the second oxide semiconductor layer 122. The reduced layer 140 may have a thickness of about 0.3 nm to about 1 nm, but is not necessarily limited thereto.

The reduced layer 140 may be disposed between the ferroelectric layer 150 and the channel layer 120.

The first oxide semiconductor layer 121, the second oxide semiconductor layer 122, the reduced layer 140, and the ferroelectric layer 150 may be sequentially arranged in a thickness direction of the channel layer 120.

According to one example embodiment, the first oxide semiconductor layer 121 including an n-type material and the second oxide semiconductor layer 122 including a p-type material may form an n-p junction shape. Electrons, which are minority carriers of the second oxide semiconductor layer 122, may be provided from the first oxide semiconductor layer 121. When minority carriers are supplied to the second oxide semiconductor layer 122, charge inversion and polarization switching are possible, thereby improving the performance of the semiconductor device.

According to another example embodiment, when the first oxide semiconductor layer 121 including a p-type material and the second oxide semiconductor layer 122 including an n material are formed, the channel layer 120 of the semiconductor device 100 may have a p-n junction form. Holes, which are minority carriers of the second oxide semiconductor layer 122, may be provided from the first oxide semiconductor layer 121. When the minority carriers are supplied to the second oxide semiconductor layer 122, charge inversion and polarization switching are possible, thereby improving the performance of the semiconductor device.

The ferroelectric layer 150 is provided on the channel layer 120. A ferroelectric material is a material having ferroelectricity in which internal electric dipole moments are aligned to maintain spontaneous polarization. The ferroelectric material has remnant polarization by dipoles even when no external electric field is applied. A polarization direction of the ferroelectric layer 150 may be changed by applying an electric field greater than a coercive field to the ferroelectric layer 150, and a threshold voltage of the semiconductor device 100 may be changed depending on the polarization direction of the ferroelectric layer 150. In this respect, the semiconductor device 100 may be applied to, for example, a non-volatile memory device.

The ferroelectric layer 150 may include, for example, a fluorite-based material or perovskite. Perovskites may include, for example, PZT, BaTiO₃, PbTiO₃, etc. Fluorite-based materials may include, for example, Hf. Fluorite-based materials may further include at least one of Si, Al, Zr, Y, La, Gd, and Sr.

As a specific example, the ferroelectric layer 150 may include at least one of hafnium oxide (HfO), zirconium oxide (ZrO), and hafnium-zirconium oxide (HfZrO). Hafnium oxide (HfO), zirconium oxide (ZrO), and hafnium-zirconium oxide (HfZrO) constituting the ferroelectric layer 150 may have a crystal structure of an orthorhombic crystal system.

To control the remanent polarization and coercive electric field of the ferroelectric layer 150, the ferroelectric layer 150 may further include a desired (or alternatively, predetermined) dopant. For example, the dopant may include at least one selected from Si, Al, Y, La, Gd, Mg, Ca, Sr Ba, Ti, Zr, Hf, and N. But this is just an example. The remanent polarization of the ferroelectric layer 150 may be determined by the type of ferroelectric material, type of dopant, dopant ratio, orientation, etc.

The gate electrode 160 is provided on the ferroelectric layer 150. For example, the gate electrode 160 may have a conductivity of approximately 1 Mohm/square or less. However, example embodiments are not limited thereto. The gate electrode 160 may include a metal or metal nitride. For example, the metal may include aluminum (Al), tungsten (W), molybdenum (Mo), titanium (Ti), or tantalum (Ta), and the metal nitride may include titanium nitride (TiN) or tantalum nitride (TaN).

The gate electrode 160 may include metal carbide, polysilicon, or a two-dimensional conductive material. The metal carbide may include a metal carbide doped (or including) aluminum or silicon. As some specific examples, the metal carbide may include TiAlC, TaAlC, TiSiC, or TaSiC. The gate electrode 160 may have a structure in which a plurality of materials are stacked. For example, the gate electrode 160 may have a stacked structure of a metal nitride layer/a metal layer, such as TiN/Al, or a stacked structure of a metal nitride layer/a metal carbide layer/metal layer, such as TiN/TiAlC/W.

In the semiconductor device 100 according to an example embodiment, the first oxide semiconductor layer 121, the second oxide semiconductor layer 122 having a different polarity from the first oxide semiconductor layer 121, and the reduced layer 140 may be formed by reducing one surface of an oxide semiconductor layer using a metal precursor having high reducing power. The first oxide semiconductor layer 121 and the second oxide semiconductor layer 122 are located adjacent to each other to form a channel layer having a p-n junction or n-p junction. The first oxide semiconductor layer 121 may provide minority carriers to the second oxide semiconductor layer 122.

Because minority carriers (holes or electrons) that may help the depletion operation and inversion operation of the second oxide semiconductor layer 122 are supplied from the first oxide semiconductor layer 121, the polarization direction of the ferroelectric layer may be changed with a relatively low voltage. Accordingly, a large operating voltage width (a memory window (MW)) and excellent retention characteristics of the semiconductor device 100 may be secured.

According to an example embodiment, the insulating layer 111 may be disposed between the substrate 110 and the first oxide semiconductor layer 121. For example, the insulating layer 111 may include at least one of silicon oxide and germanium oxide, but is not limited thereto, and may further include a material capable of providing insulation between adjacent material layers. Further, the insulating layer 111 may include oxide or oxynitride of a Group IV semiconductor material. For example, the insulating layer 111 may include SiO₂, GeO₂, SiGeO₄, SiON, GeON, SiGeON, etc. However, this is just an example.

FIG. 2 is a schematic cross-sectional view of a semiconductor device 200 according to an example embodiment. The semiconductor device 200 shown in FIG. 2 maybe a field effect transistor.

Referring to FIG. 2, the semiconductor device 200 according to an example embodiment includes a substrate 210, an insulating layer 211 on the substrate 210, a channel layer 220 on the insulating layer 211, a reduced layer 240 on the channel layer 220, a ferroelectric layer 250 on the reduced layer 240, and a gate electrode 260 on the ferroelectric layer 250. The substrate 210, the insulating layer 211, the channel layer 220, the reduced layer 240, the ferroelectric layer 250, and the gate electrode 260 correspond to the substrate 110, the insulating layer 111, the channel layer 120, the reduced layer 140, the ferroelectric layer 150, and gate electrode 160 of FIG. 1, and thus, detailed descriptions thereof will be omitted. The semiconductor device 200 may not include at least one of the substrate 210 and the insulating layer 211.

The semiconductor device 200 may further include a source electrode 231 and a drain electrode 232 that are spaced apart from each other and are electrically connected to the channel layer 220. The source electrode 231 and the drain electrode 232 may directly contact a layer including majority carriers of the channel layer 120, for example, the second oxide semiconductor layer 222. An insulating layer 212 may further be disposed between the first oxide semiconductor layer 121 and the source and drain electrodes 231 and 232. This is to mitigate or prevent an electrical short because the first oxide semiconductor layer 121 includes minority carriers. In FIG. 2, the source electrode 231 and the drain electrode 232 are shown as being disposed at both ends of the channel layer 220, but the arrangement is not limited thereto. The source electrode 231 and the drain electrode 232 may be disposed on the lower surface of an oxide semiconductor layer including majority carriers of the channel layer 120, for example, the first oxide semiconductor layer 221.

The source electrode 231 and the drain electrode 232 may include a metal material with excellent electrical conductivity, such as Ag, Au, Pt, or Cu, but are not limited thereto.

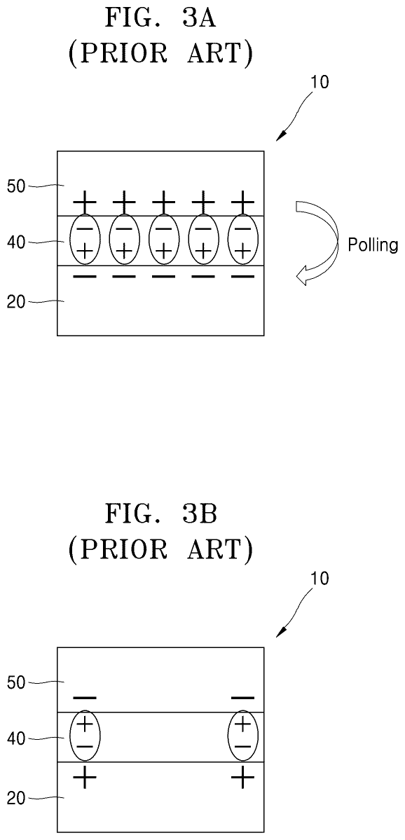

FIGS. 3A and 3B are diagrams for explaining an operation of a ferroelectric field effect transistor 10 of the related art.

Referring to FIGS. 3A and 3B, the ferroelectric field effect transistor 10 of the related art includes a channel layer 20 including an oxide semiconductor having a plurality of carriers of a desired (or alternatively, predetermined) polarity, a ferroelectric layer 40 provided on the channel layer 20, and a gate 50 provided on the ferroelectric layer 40. FIGS. 3A and 3B illustrate a case in which the channel layer 20 includes an n-type oxide semiconductor (e.g., IGZO) having electrons as major carriers.

FIG. 3A shows a polarization state within the ferroelectric layer 40 when a positive (+) voltage is applied to the gate 50, and FIG. 3B shows a polarization state within the ferroelectric layer 40 when a negative (−) voltage is applied to the gate 50.

In order to change the polarization direction of the ferroelectric layer 40, an electric field greater than a coercive field must be applied to the ferroelectric layer 40. However, in the ferroelectric field effect transistor 10 of the related art, because holes, which are minority carriers are insufficient in the channel layer 20, when a negative (−) voltage is applied to the gate 50 as shown in FIG. 3B, a charge screening does not occur, and accordingly, the polarization direction of the ferroelectric layer 40 may not be changed. Therefore, in the ferroelectric field effect transistor 10 of the related art, the operating voltage width (MW) is small and retention characteristics may be deteriorated.

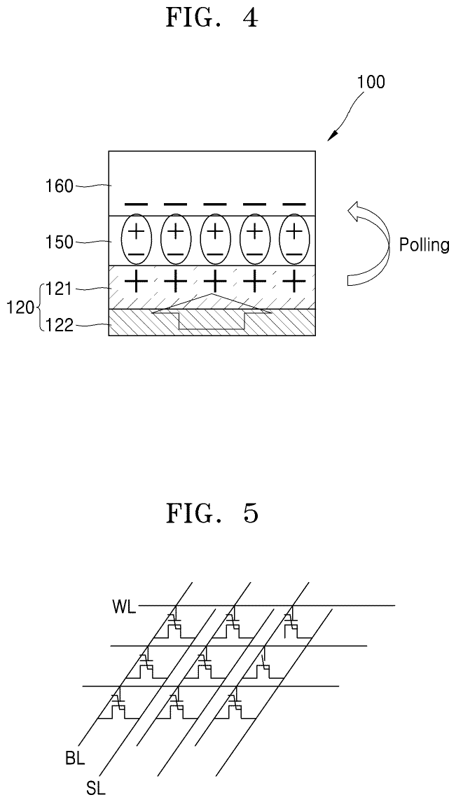

FIG. 4 illustrates a polarization state within a ferroelectric layer when a negative (−) voltage is applied to a gate electrode in a semiconductor device according to an example embodiment.

The channel layer 120 may be formed by reducing a lower surface of the oxide semiconductor layer after sequentially forming the oxide semiconductor layer, the ferroelectric layer 150, and the gate electrode 160. Although not shown in the drawing, the reduced layer may be disposed on a lower surface of the first oxide semiconductor layer 121. The channel layer 120 may include an n-type oxide semiconductor having electrons as majority carriers. From another point of view, the channel layer 120 may include a first oxide semiconductor layer 121 and a second oxide semiconductor layer 122 having different oxygen concentrations. For example, the first oxide semiconductor layer 121 may include SnO₂, and the second oxide semiconductor layer 122 may include SnO. The second oxide semiconductor layer 122 may be a layer formed by reducing a material including SnO₂. A relative positional relationship between the first oxide semiconductor layer 121 and the second oxide semiconductor layer 122 in FIG. 4 maybe opposite to the relative positional relationship between the first oxide semiconductor layer 121 and the second oxide semiconductor layer 122 in FIG. 1. That is, the first oxide semiconductor layer 121 in FIG. 4 is in contact with the ferroelectric layer 150, while the first oxide semiconductor layer 121 in FIG. 1 maybe spaced apart from the ferroelectric layer 150. The relative position between the first oxide semiconductor layer 121 and the second oxide semiconductor layer 122 may vary depending on a region where the oxide semiconductor layer is reduced.

Referring to FIG. 4, when a negative (−) voltage is applied to the gate electrode 160, the second oxide semiconductor layer 122 having p-type semiconductor characteristics supplies holes, which are minority carriers to the first oxide semiconductor layer 121 having n-type semiconductor characteristics due to a tunneling effect, and thus, the polarization direction of the ferroelectric layer 150 may be changed. Because the reduced layer 140 does not affect the polarization phenomenon of the ferroelectric layer 150, the reduced layer 140 is not shown. Therefore, because the polarization direction of the ferroelectric layer 150 may be changed even with a relatively low voltage, the semiconductor device 100 with a large operating voltage width (MW) and excellent retention characteristics may be implemented.

Up to now, it has been described that the oxide semiconductor layer of the channel layer 120, which is closer to the ferroelectric layer 150, includes majority carriers, and the oxide semiconductor layer of the channel layer 120, which is located farther from the ferroelectric layer 150, includes minority carriers, but example embodiments are not limited thereto. Among the oxide semiconductor layers, a non-reduced oxide semiconductor layer (for example, the first oxide semiconductor layer 121) may include majority carriers. Additionally, the reduced layer 140 may be in contact with a layer having a low oxygen content among the first oxide semiconductor layer 121 and the second oxide semiconductor layer 122.

FIG. 5 shows an equivalent circuit diagram of a memory device including the semiconductor device 200 according to the embodiment shown in FIG. 2.

Referring to FIG. 5, the memory device may include a plurality of semiconductor devices 200 arranged in two dimensions. At this time, the plurality of semiconductor devices 200 may include the semiconductor device 200 shown in FIG. 2. Additionally, the semiconductor device 200 may include a plurality of bit lines BL, a plurality of selection lines SL, and a plurality of word lines WL. The selection line SL may be electrically connected to a source electrode of the semiconductor device 200, the bit line BL may be electrically connected to a drain electrode of the semiconductor device 200, and the plurality of word lines WL may be electrically connected to a gate electrode of the semiconductor device 200. Additionally, the semiconductor device 200 may further include an amplifier (not shown) to amplify a signal output from the bit line BL.

In FIG. 5, although the equivalent circuit diagram is shown in a two-dimensional plane for convenience, the semiconductor device 200 may have a stacked structure of two or more layers. For example, the plurality of bit lines BL and the plurality of selection lines SL extending in a vertical direction may be arranged in two dimensions, and the plurality of word lines WL extending in a horizontal direction may each be arranged in a plurality of layers. However, example embodiments are not necessarily limited thereto, and the semiconductor devices 200 may be arranged in various ways, for example, in three dimensions.

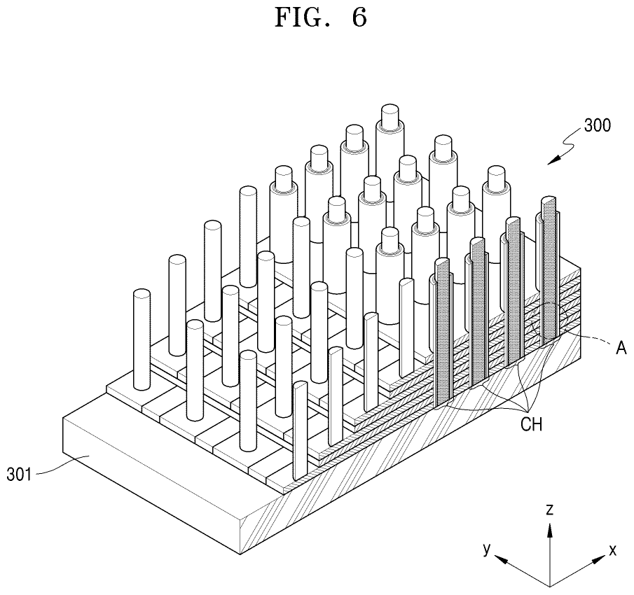

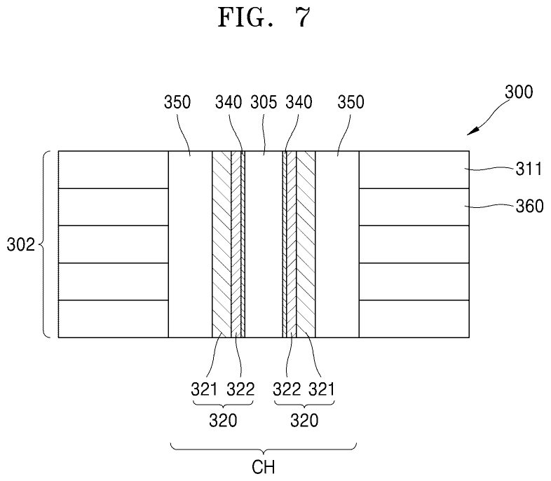

FIG. 6 is a perspective view of a semiconductor device 300 according to another embodiment, and FIG. 7 is an enlarged cross-sectional view of portion ‘A’ of FIG. 6. The semiconductor device 300 shown in FIG. 6 maybe a memory cell string of three-dimensional (3D) (or vertical) NAND (e.g., VNAND) or 3D FeFET memory.

Referring to FIGS. 6 and 7, a plurality of gate electrodes 360 and a plurality of insulating elements 311 may be alternately arranged on a substrate 301. The plurality of gate electrodes 360 and the plurality of insulating elements 311 may be sequentially stacked while crossing in the thickness direction of the substrate 301. The gate electrode 360 corresponds to the gate electrode 160 described with reference to FIG. 1. Each gate electrode 360 is connected to one of a word line (not shown) or a string select line (not shown).

A channel hole CH that vertically penetrates the plurality of gate electrodes 360 and the plurality of insulating elements 311 that are arranged alternately is provided.

The channel hole CH may include multiple layers. The channel hole CH may include a pillar 305 extending in a thickness direction of the substrate 301, a reduced layer 340 surrounding a side surface of the pillar 305, a channel layer 320 surrounding a side surface of the reduced layer 340, and a ferroelectric layer 350 surrounding a side surface of the channel layer 320. Also, the channel layer 320 may include a second oxide semiconductor layer 322 and a first oxide semiconductor layer 321. In FIG. 7, the first oxide semiconductor layer 321 may include majority carriers of the channel layer 320, and the second oxide semiconductor layer 322 may include minority carriers of the channel layer 320.

The reduced layer 340, the channel layer 320, and the ferroelectric layer 350 correspond to the reduced layer 140, the channel layer 120, and the ferroelectric layer 150 described with reference to FIG. 1, and thus, the detailed descriptions thereof are omitted. The pillar 305 may include silicon oxide. In other words, the pillar 305 may extend in a direction perpendicular to a surface of the substrate 301.

A common source region (not shown) is provided on the substrate 301. For example, the common source region may have a second type that is different from the type of the substrate 301. For example, the common source region may have n-type. Hereinafter, it is assumed that the common source region is n-type. However, the common source region is not limited to n-type.

One end of the channel layer 320 may be in contact with a common source region, and the other end of the channel layer 320 may be in contact with a drain (not shown). For example, the drain may include a silicon material doped with n-type.

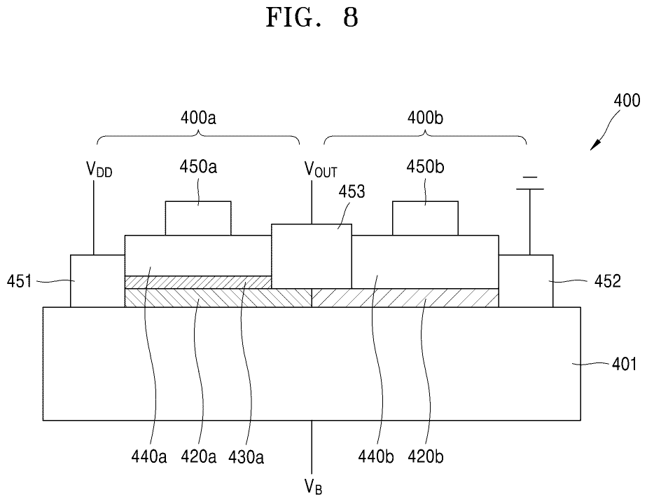

FIG. 8 shows a semiconductor device 400 according to an example embodiment.

The semiconductor device 400 shown in FIG. 8 maybe, for example, an inverter used to construct a logic circuit in, for example, NOR flash or NAND flash.

Referring to FIG. 8, the semiconductor device 400 includes first and second field effect transistors 400a and 400b provided on a substrate 401. Here, each of the first and second field effect transistors 400a and 400b may be a ferroelectric field effect transistor. A Si substrate may be used as the substrate 401, but this is an example.

The first field effect transistor 400a may include a first channel layer 420a, a first ferroelectric layer 440a provided on the first channel layer 420a, and a first gate electrode 450a provided on the first ferroelectric layer 440a. A reduced layer 430a may further be disposed between the first channel layer 420a and the first ferroelectric layer 440a.

The second field effect transistor 400b may include a second channel layer 420b, a second ferroelectric layer 440b provided on the second channel layer 420b, and a second gate electrode 450b provided on the second ferroelectric layer 440b.

The first field effect transistor 400a may include a first electrode 451, and the second field effect transistor 400b may include a second electrode 452, and the first and second field effect transistors 400a and 400b may share a third electrode 453. The first electrode 451 may be a source electrode of the first field effect transistor 400a, the second electrode 451 may be a source electrode of the second field effect transistor 400b, and the third electrode 453 may be a drain electrode (e.g., a common drain electrode) of both the first and second field effect transistors 400a and 400b. In the drawing, it is shown that the first and second field effect transistors 400a and 400b share the third electrode 453, but the disclosure is not limited thereto. The third electrode 453 may be separated into two electrodes for the first and second field effect transistors 400a and 400b, respectively.

A material of the first channel layer 420a may correspond to the material of the second oxide semiconductor layer 122 described with reference to FIG. 1, and a material of the second channel layer 420b may correspond to the material of the first oxide semiconductor layer 121 described with reference to FIG. 1. After forming an oxide semiconductor layer, the first channel layer 420a, the reduced layer 430, and the second channel layer 420b may be formed by reducing a portion of the oxide semiconductor layer corresponding to the first channel layer 420a by using a metal precursor. At this time, the thickness of the first channel layer 420a and the thickness of the second channel layer 420b may be substantially the same. Here, the oxide semiconductor layer may be an oxide including at least one of Si, Sn, and Ni.

A semiconductor device according to an example embodiment may not include a reduced layer. For example, after forming the first oxide semiconductor layer, the second oxide semiconductor layer, and the reduced layer, the reduced layer may be removed. In some example embodiments, a first oxide semiconductor layer and a second oxide semiconductor layer having different polarities may be formed without the reduced layer.

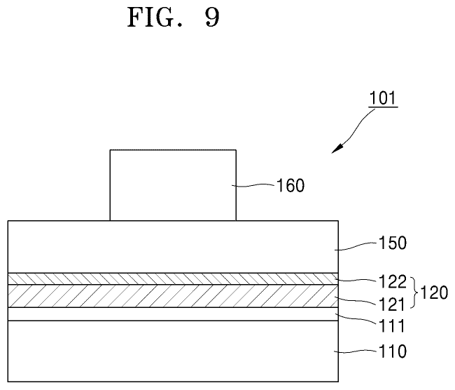

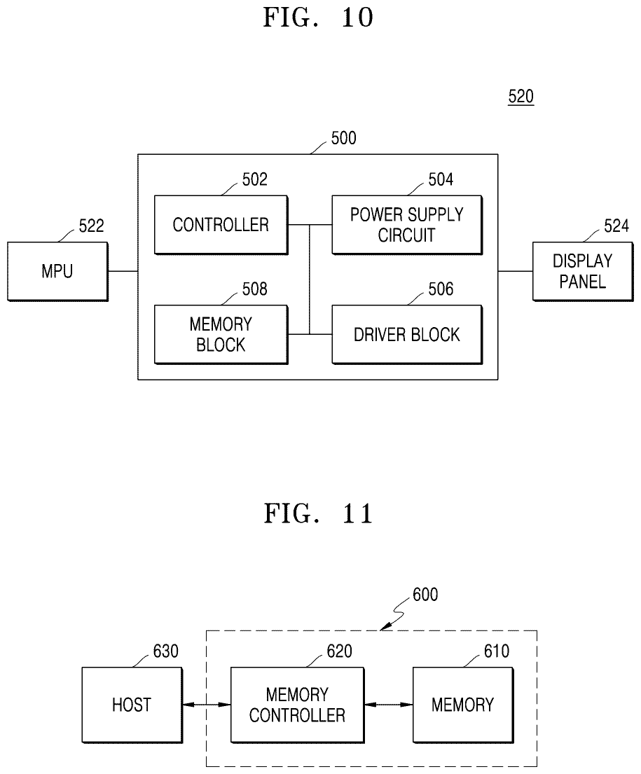

FIG. 9 is a diagram illustrating a semiconductor device 101 according to an example embodiment. Referring to FIGS. 1 and 9, the semiconductor device 101 of FIG. 9 may include only a first oxide semiconductor layer 121 and a second oxide semiconductor layer 122 without a reduced layer. When the second oxide semiconductor layer 122 is formed using a gas atmosphere with high reducing power, the reduced layer may not need to be formed. In some example embodiments, the semiconductor device 101 may be formed by removing a previously formed reduced layer and forming the ferroelectric layer 140 on the second oxide semiconductor layer 122.

FIG. 10 is a schematic block diagram of a display driver integrated circuit (DDI) 500 and a display device 520 including the DDI 500 according to an example embodiment.

Referring to FIG. 10, the DDI 500 may include a controller 502, a power supply circuit 504, a driver block 506, and a memory block 508. The controller 502 receives and decodes a command applied from a main processing unit (MPU) 522, and controls each block of the DDI 500 to implement an operation according to the command. The power supply circuit 504 generates a drive voltage in response to the control of the controller 502. The driver block 506 drives a display panel 524 using a driving voltage generated by the power supply circuit 504 in response to the control of the controller 502. The display panel 524 may be, for example, a liquid crystal display panel, an organic light emitting device (OLED) display panel, or a plasma display panel. The memory block 508 is a block that temporarily stores commands input to the controller 502 or control signals output from the controller 502, or stores necessary or desired data, and may include a memory, such as RAM or ROM. For example, the memory block 508 may include semiconductor devices according to the above example embodiments described above.

FIG. 11 is a block diagram of an electronic apparatus 600 according to an example embodiment.

Referring to FIG. 11, the electronic apparatus 600 includes a memory 610 and a memory controller 620. The memory controller 620 may control the memory 610 to read data from and/or write data to the memory 610 in response to a request from a host 630. The memory 610 may include a semiconductor device according to the example embodiments described above.

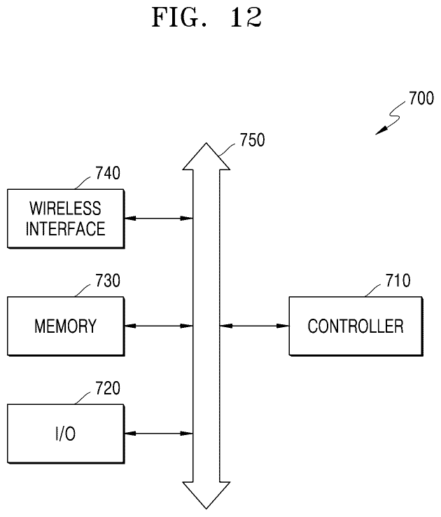

FIG. 12 is a block diagram of an electronic apparatus 700 according to an example embodiment.

Referring to FIG. 12, the electronic apparatus 700 may constitute a wireless communication device, or a device capable of transmitting and/or receiving information in a wireless environment. The electronic apparatus 700 includes a controller 710, an input/output device (I/O) 720, a memory 730, and a wireless interface 740, which are each interconnected through a bus 750.

The controller 710 may include at least one of a microprocessor, a digital signal processor, or a similar processing device. The input/output device 720 may include at least one of a keypad, a keyboard, or a display. The memory 730 may be used to store instructions executed by the controller 710. For example, the memory 730 may be used to store user data. The electronic apparatus 700 may use the wireless interface 740 to transmit/receive data through a wireless communication network. The wireless interface 740 may include an antenna and/or a wireless transceiver. In some embodiments, the electronic apparatus 700 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA). The memory 730 of the electronic apparatus 700 may include a semiconductor device according to the example embodiments described above.

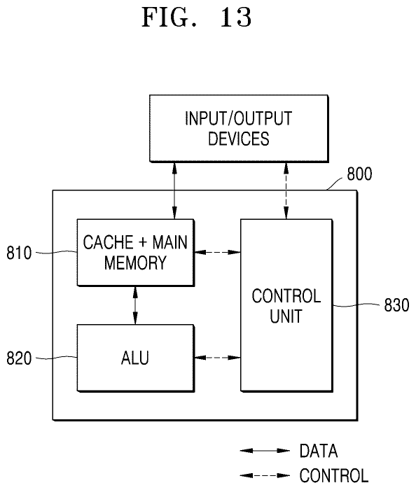

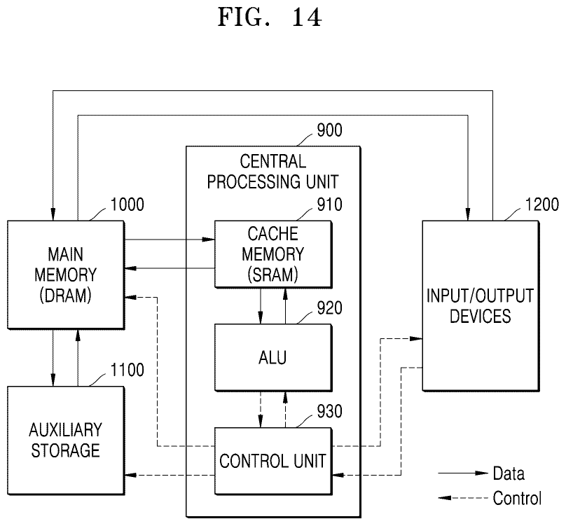

FIGS. 13 and 14 are conceptual diagrams schematically showing a device architecture that may be applied to an electronic apparatus according to some example embodiments.

Referring to FIG. 13, the electronic device architecture 800 may include a memory unit 810 and a control unit 830, and may further include an arithmetic logic unit (ALU) 820. The memory unit 810, the ALU 820, and the control unit 830 may be electrically connected to each other. For example, the electronic device architecture 800 may be implemented as a single chip including the memory unit 810, the ALU 820, and the control unit 830. In some example embodiments, the memory unit 810, the ALU 820, and the control unit 830 may be mutually interconnected on an on-chip through a metal line and may communicate directly to each other. The memory unit 810, the ALU 820, and the control unit 830 may be monolithically integrated on one substrate to form one chip. An input/output device 2000 maybe connected to the electronic device architecture (chip) 800. Additionally, the memory unit 810 may include both main memory and cache memory. The electronic device architecture (chip) 800 may be an on-chip memory processing unit. The memory unit 810, the ALU 820, and/or the control unit 830 may each independently include semiconductor devices according to the embodiments described above.

Referring to FIG. 14, a cache memory 910, an ALU 920, and a control unit 930 may constitute a central processing unit (CPU) 900, and the cache memory 910 may include static random access memory (SRAM). Separately from the CPU 900, a main memory 1000 and an auxiliary storage 1100 maybe provided, and an input/output device 1200 may also be provided. The main memory 1000 maybe, for example, dynamic random access memory (DRAM), and may include semiconductor devices according to the embodiments described above.

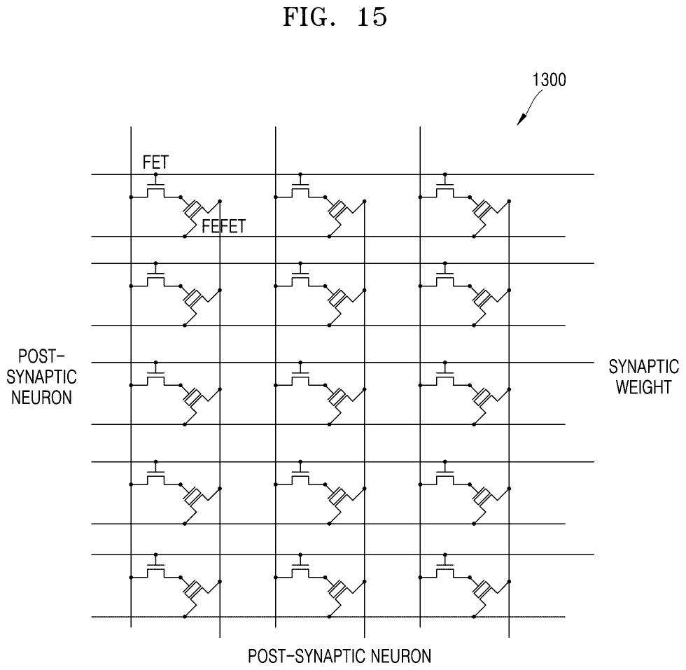

The semiconductor device (ferroelectric field effect transistor) described above may be applied to an artificial intelligence device 1300 shown in FIG. 15. Each memory cell constituting the artificial intelligence device 1300 includes one field effect transistor (FET) and one ferroelectric field effect transistor (FEFET). Here, the ferroelectric field effect transistor (FEFET) may be one of the semiconductor devices according to the example embodiments described above. As synaptic weight is applied to the transistor, a potential may be transmitted to the ferroelectric, and thus, the memory state may be changed. At this time, when a potential greater than a threshold voltage is applied to the ferroelectric, a neuron-synapse operation in which the potential of a pre-synaptic neuron is transmitted to the post-synaptic neuron may occur.

In some cases, the electronic device architecture may be implemented in a form in which computing unit devices and memory unit devices are adjacent to each other on one chip without division of sub-units.

According to some example embodiments, because a semiconductor device including a ferroelectric layer includes a plurality of layers having different polarities, a sub-layer may provide minority carriers to a main layer.

According to some example embodiments, a semiconductor device including a ferroelectric layer may secure a large operation voltage width (a memory window (MW)) and excellent retention characteristics by providing minority carriers.

According to some example embodiment, a semiconductor device including a ferroelectric layer may be implemented as an inverter using metal oxide layers having different oxygen contents.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that the example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer including an n-type oxide semiconductor layer and a p-type oxide semiconductor layer;
a ferroelectric layer on the channel layer;
a gate electrode on the ferroelectric layer; and
a reduced layer on the channel layer and including an element having greater reducing power than a metal included in the channel layer.

2. The semiconductor device of claim 1, wherein the element included in the reduced layer is metal having greater reducing power than a metal included in the channel layer.

3. The semiconductor device of claim 1, wherein the n-type oxide semiconductor layer and the p-type oxide semiconductor layer include different oxygen contents.

4. The semiconductor device of claim 3, wherein the reduced layer is in contact with one of the n-type oxide semiconductor layer and the p-type oxide semiconductor layer that has a relatively low oxygen content.

5. The semiconductor device of claim 1, wherein the reduced layer is spaced apart from one of the n-type oxide semiconductor layer and the p-type oxide semiconductor layer, and in contact with the other one of the n-type oxide semiconductor layer and the p-type oxide semiconductor layer.

6. The semiconductor device of claim 5, wherein a thickness of one of the n-type oxide semiconductor layer and the p-type oxide semiconductor layer that is in contact with the reduced layer is less than a thickness of the other one of the n-type oxide semiconductor layer and the p-type oxide semiconductor layer that is spaced apart from the reduced layer.

7. The semiconductor device of claim 1, wherein a thickness of the reduced layer is less than or equal to a thickness of one of the n-type oxide semiconductor layer and the p-type oxide semiconductor layer that is in contact with the reduced layer.

8. The semiconductor device of claim 1, wherein the n-type oxide semiconductor layer and the p-type oxide semiconductor layer include same metal.

9. The semiconductor device of claim 1, wherein the reduced layer is between the ferroelectric layer and the channel layer.

10. The semiconductor device of claim 1, wherein the n-type oxide semiconductor layer and the p-type oxide semiconductor layer are parallel to each other in a thickness direction of the channel layer.

11. The semiconductor device of claim 1, wherein a thickness of the reduced layer is 1 nm or less.

12. The semiconductor device of claim 1, wherein at least one of the n-type oxide semiconductor layer and the p-type oxide semiconductor layer includes at least one of indium oxide, zinc oxide, tin oxide, nickel oxide, and gallium oxide.

13. The semiconductor device of claim 1, wherein the reduced layer includes at least one of aluminum oxide, hafnium oxide, and silicon oxide.

14. The semiconductor device of claim 1, further comprising:
a source electrode on the channel layer and spaced apart from the gate electrode; and
a drain electrode on the channel layer and spaced apart from the gate electrode and the source electrode.

15. The semiconductor device of claim 1, further comprising:
a pillar extending in a first direction,
wherein the channel layer surrounds the pillar,
the ferroelectric layer surrounds the channel layer,
the gate electrode surrounds the ferroelectric layer, and
the reduced layer is between the pillar and the channel layer.

16. The semiconductor device of claim 15, wherein the n-type oxide semiconductor layer and the p-type oxide semiconductor layer are parallel in a direction perpendicular to the first direction.

17. The semiconductor device of claim 16, wherein the gate electrode includes a plurality of gate electrodes being apart from each other in the first direction.

18. The semiconductor device of claim 1, wherein
the n-type oxide semiconductor layer and the p-type oxide semiconductor layer are parallel with each other in a direction perpendicular to a thickness direction of the channel layer,
the ferroelectric layer includes,
a first ferroelectric layer on the n-type oxide semiconductor layer; and
a second ferroelectric layer on the p-type oxide semiconductor layer and spaced apart from the first ferroelectric layer, the gate electrode includes,
a first gate electrode on the first ferroelectric layer, and
a second gate electrode on the second ferroelectric layer and spaced apart from the first gate electrode, and
the reduced layer is in contact with one of the n-type oxide semiconductor layer and the p-type oxide semiconductor layer, and is not in contact with the other one of the n-type oxide semiconductor layer and the p-type oxide semiconductor layer.

19. The semiconductor device of claim 18, wherein a thickness of the n-type oxide semiconductor layer is substantially same as a thickness of the p-type oxide semiconductor layer.

20. The semiconductor device of claim 18, further comprising:
a common drain electrode in contact with both the n-type oxide semiconductor layer and the p-type oxide semiconductor layer;
a first source electrode in contact with the n-type oxide semiconductor layer; and
a second source electrode in contact with the p-type oxide semiconductor layer.
